(19) United States
(12) Patent Application Publication
(10) Pub. No.: US 2015/0090948 A1
(43) Pub. Date: Apr. 2, 2015

(54) RESISTIVE MEMORY APPARATUS AND MANUFACTURING METHOD THEREOF

(71) Applicant: SK hynix Inc., Gyeonggi-do (KR)

(72) Inventor: Min Seok SON, Gyeonggi-do (KR)

(73) Assignee: SK hynix Inc., Gyeonggi-do (KR)

(21) Appl. No.: 14/150,558

(22) Filed: Jan. 8, 2014

(30) Foreign Application Priority Data
Sep. 30, 2013 (KR) 10-2013-0116400

(51) Int. Cl. H01L 45/00

(52) U.S. Cl. CPC H01L 45/144; H01L 45/1608
USPC 257/2; 438/382

(57) ABSTRACT

A resistive memory apparatus includes a first electrode formed on a semiconductor substrate, an insulating layer formed on the first electrode and including a hole exposing an upper surface of the first electrode, a data storage unit in which a first resistance-variable material and a second resistance-variable material are alternately formed in the hole at least once, and a second electrode formed on the data storage unit.

### CROSS-REFERENCES TO RELATED APPLICATION

This application claims priority under 35 U.S.C. 119(a) to Korean application No. 10-2013-0116400, filed on Sep. 30, 2013, in the Korean intellectual property Office, which is incorporated herein by reference in its entirety.

### BACKGROUND

1. Technical Field

Various embodiments of the present invention relate to a semiconductor technology, and more particularly, to a resistive memory apparatus having a multi-level cell, a manufacturing method thereof.

2. Related Art

In recent years, with demands on high performance and low power of semiconductor apparatuses, next generation memory apparatuses with non-volatility and non-refresh characteristics have been researched. As one of the next generation memory apparatuses, resistive memory apparatuses are suggested, and typical examples of the resistive memory apparatuses are a phase-change random access memory (PCRAM), a resistive RAM (ReRAM), a magnetic RAMs (MRAMs), a spin-transfer torque magnetoresistive RAM (STTMRAM), and a polymer RAM (PoRAM).

Reduction of a cell pitch or an area occupying by one cell is required for accomplishing high integration in the resistive memory apparatuses.

However, the process for the reduction may be very complicated, and electrical characteristics and reliability of the resistive memory apparatus may be degraded due to a void formed in a data storage unit during the process.

A multi-level cell (MLC) that may store multi-bits in a unit memory cell has been introduced to implement resistive memory apparatus with high integration and large capacity.

### SUMMARY

Various exemplary embodiments of the present invention are directed to a resistive memory apparatus with high integration and large capacity by implementing a multi-level cell, a manufacturing method thereof.

According to an aspect of an embodiment of the present invention, a resistive memory apparatus may include a first electrode formed on a semiconductor substrate, an insulating layer formed on the first electrode and including a hole exposing an upper surface of the first electrode, a data storage unit in which a first resistance-variable material and a second resistance-variable material having different resistances from each other are alternately formed at least once in the hole, and a second electrode formed on the data storage unit.

According to an aspect of another embodiment, a resistive memory apparatus may include a first electrode formed on a semiconductor substrate, an insulating layer formed on the first electrode and including a hole exposing an upper surface of the first electrode, a data storage unit formed in the hole and including at least two resistance-variable materials having different composition ratios from each other and formed to extend upward from the upper surface of the first electrode, and a second electrode formed on the data storage unit.

According to an aspect of another embodiment, a resistive memory apparatus may include a first electrode formed on a semiconductor substrate, an interlayer insulating layer formed on the first electrode and including a hole exposing an upper surface of the first electrode, a first data storage unit formed at a sidewall of the hole, a second data storage unit formed to be buried in the hole, an insulating layer formed between the first data storage unit and the second data storage unit, and a second electrode formed on the first data storage unit, the insulating layer, and the second data storage unit.

According to an aspect of another embodiment, a resistive memory apparatus may include a memory cell array including memory cells, each memory cell including two or more resistance-variable materials for supporting a multi-level cell having different resistances from each other and alternately formed, and a control circuit configured to control two-bit data or more among data input from the outside to be stored in a unit memory cell.

According to an aspect of another embodiment, a method of manufacturing a resistive memory apparatus may include forming a first electrode on a semiconductor substrate, forming an insulating layer on the semiconductor substrate, forming a hole exposing an upper surface of the first electrode by etching the insulating layer, forming a data storage unit, including a first resistance-variable material and a second resistance-variable material having different resistances from each other, in the hole, and forming a second electrode on the data storage unit.

According to an aspect of another embodiment, a resistive memory apparatus may include a switching device coupled to a word line, a first electrode coupled to the switching device, a second electrode coupled to a bit line, and a data storage unit including a first resistance-variable material and a second resistance-variable material having different resistances from each other, wherein the first resistance-variable material and the second resistance-variable material are connected in parallel between the first electrode and the second electrode.

These and other features, aspects, and embodiments are described below in the section entitled “DETAILED DESCRIPTION”.

### BRIEF DESCRIPTION OF THE DRAWINGS

The above and other aspects, features and other advantages of the subject matter of the present disclosure will be more clearly understood from the following detailed description taken in conjunction with the accompanying drawings, in which:

FIG. 1 is a block diagram illustrating a resistive memory apparatus;

FIG. 2 is a circuit diagram illustrating a memory cell of a resistive memory apparatus;

FIG. 3 is a cross-sectional view illustrating a resistive memory apparatus according to an embodiment of the inventive concept;

FIGS. 4A to 4D are cross-sectional views sequentially illustrating a method of manufacturing the resistive memory apparatus shown in FIG. 3;

FIG. 5 is a cross-sectional view illustrating a resistive memory apparatus according to another embodiment of the inventive concept; and

FIGS. 6A to 6E are cross-sectional views sequentially illustrating a method of manufacturing the resistive memory apparatus shown in FIG. 5.

### DETAILED DESCRIPTION

Hereinafter, exemplary embodiments will be described in detail with reference to the accompanying drawings.

Exemplary embodiments are described herein with reference to cross-sectional illustrations that are schematic illustrations of exemplary embodiments (and intermediate structures). As such, variations from the shapes of the illustrations as a result, for example, of manufacturing techniques and/or tolerances, are to be expected. Thus, exemplary embodiments should not be construed as limited to the particular shapes of regions illustrated herein but may be to include deviations in shapes that result, for example, from manufacturing. In the drawings, lengths and sizes of layers and regions may be exaggerated for clarity. Throughout the disclosure, reference numerals correspond directly to the like numbered parts in the various figures and embodiments of the present invention. It is also understood that when a layer is referred to as being “on” another layer or substrate, it can be directly on the other or substrate, or intervening layers may also be present. It is also noted that in this specification, “connected/coupled” refers to one component not only directly coupling another component but also indirectly coupling another component through an intermediate component. In addition, a singular form may include a plural form as long as it is not specifically mentioned in a sentence.

Although a few embodiments of the inventive concept will be shown and described, it will be appreciated by those of ordinary skill in the art that changes may be made in these exemplary embodiments without departing from the principles and spirit of the inventive concept.

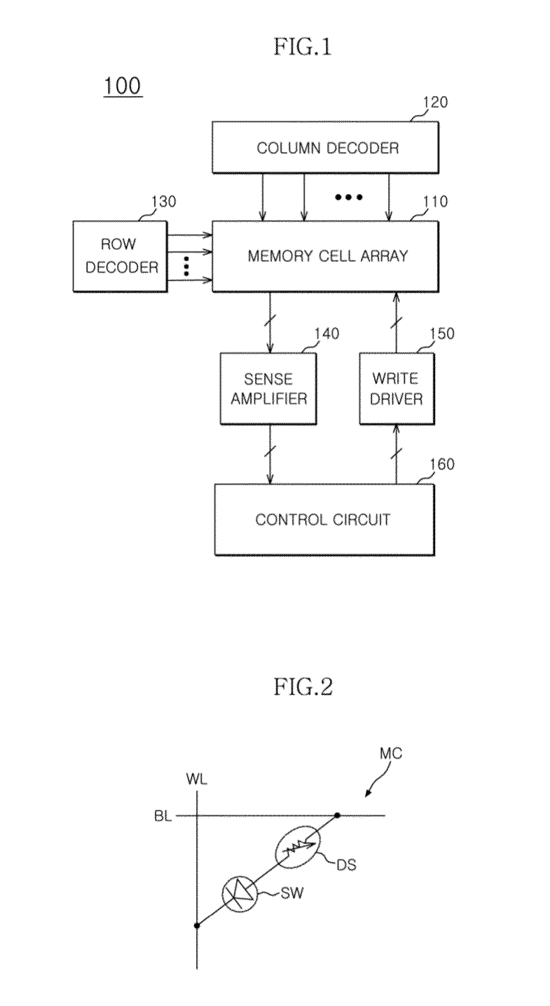

FIG. 1 is a block diagram illustrating a resistive memory apparatus, and FIG. 2 is a circuit diagram illustrating a memory cell of a resistive memory apparatus.

Referring to FIG. 1, a resistive memory apparatus 100 may include a memory cell array 110, a column decoder 120, a row decoder 130, a sense amplifier 140, a write driver 150, and a control circuit 160.

The memory cell array 110 may include a plurality of memory cells that may store data input from the outside. Here, a unit memory cell in the resistive memory apparatus 100 may be a multi-level cell that may store two-bit data or more. Referring to FIG. 2, the memory cell MC may include a data storage unit DS having two or more resistances both in a crystalline state and in an amorphous state, and a switching device SW connected in series to the data storage unit DS. For example, the data storage unit DS may include a first resistance-variable material in which two elements are combined, such as SbSe, SbTe, GaSb, InSb, InSe, or GeTe, and a second resistance-variable material in which three elements are combined, such as GeSbTe, GaSeTe, or InSbTe.

The column decoder 120 receives a column address and decodes the column address to designate a column corresponding to a memory cell to be read or written.

The row decoder 130 receives a row address, and decodes the row address to designate a row corresponding to the memory cell to be read or written.

The sense amplifier 140 verifies whether or not a resistance of a memory cell is within a preset resistance window, and provides a verifying result to the control circuit 160.

The write driver 150 provides a write current for storing data in a memory cell and adjusts an amount of the write current in response to a control signal provided from the control circuit 160.

The control circuit 160 controls two-bit data or more to be stored in a unit memory cell, and provides the control signal for adjusting the amount of the write current depending on the verifying result of the sense amplifier 140 to the write driver 150.

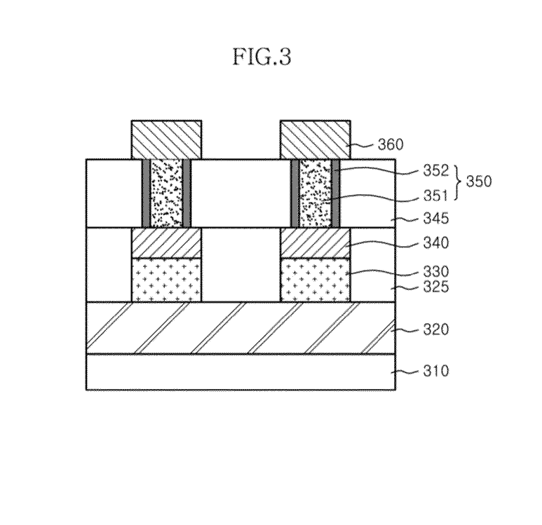

FIG. 3 is a cross-sectional view illustrating a resistive memory apparatus according to an embodiment of the present invention.

Referring to FIG. 3, the resistive memory apparatus may include a word line region 320 serving as a word line and formed on a semiconductor substrate 310, a switching device 330 formed on the word line region 320, a first electrode (or a bottom electrode) 340 formed on the switching device 330, a data storage unit 350 formed on the first electrode 340, and a second electrode (or a top electrode) 360 formed on the data storage unit 350. The reference numerals 325 and 345 denote a first interlayer insulating layer and a second interlayer insulating layer.

The data storage unit 350 may be formed so that a width of the data storage unit 350 is smaller than an upper width of the first electrode 340. Therefore, a contact area of the first electrode 340 and the data storage unit 350 is reduced. The reduced contact area allows a reset current of the resistive memory apparatus to be reduced.

The data storage unit 350 may include a first resistance-variable material 351 and a second resistance-variable material 352 formed to surround sidewall of the first resistance-variable material 351. At this time, the first resistance-variable material 351 and the second resistance-variable material 352 are formed to be in contact with the first electrode 340 and extend upward from an upper surface of the first electrode 340.

That is, the first resistance-variable material 351 and the second resistance-variable material 352 are connected in parallel between the first electrode 340 and the second electrode 360. Further, the first resistance-variable material 351 and the second resistance-variable material 352 may be alternatively disposed two times or more in a lateral direction. That is, the data storage unit 350 may further include a third resistance-variable material surrounding a sidewall of the first resistance-variable material 351 and the fourth resistance-variable material surrounding a sidewall of the third resistance-variable material. Here, the third resistance-variable material may include the same material as the second resistance-variable material 352, and the fourth resistance-variable material may include the same material as the first resistance-variable material 351.

In the data storage unit 350, a resistance-variable material for the first resistance-variable material 351 is different from a resistance-variable material for the second resistance-variable material 352. As described above, the first resistance-variable material 351 may include a material in which two elements are combined, such as SbSe, SbTe, GaSb, InSb, InSe, or GeTe, and the second resistance-variable material 352 may include a material in which three elements are combined, such as GeSbTe, GaSeTe, or InSbTe. Thus, a SET resistance is changed depending on composition of the resistance-variable material. As described above in the embodiment, when composition ratios or kinds of the resistance-variable materials are changed, the resistances are changed depending on the composition ratios or kinds to support a multi-level cell.

The switching device 330 may be configured of any one among a PN diode, a Schottky diode, and a MOS transistor. When the switching device 330 is configured of a diode, the memory cell may further include an ohmic contact layer that may improve adhesion between the diode formed of polysilicon and the first electrode 340 formed of a metal material.

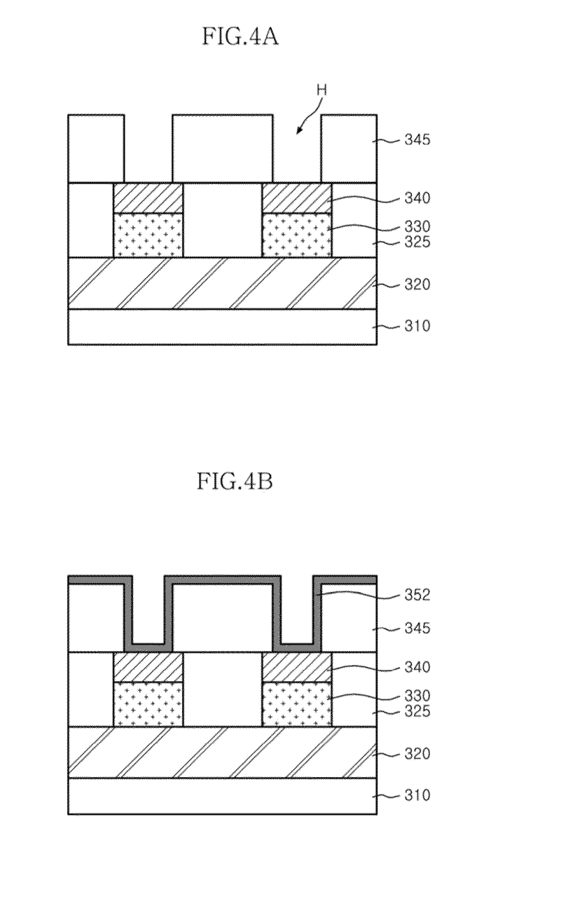

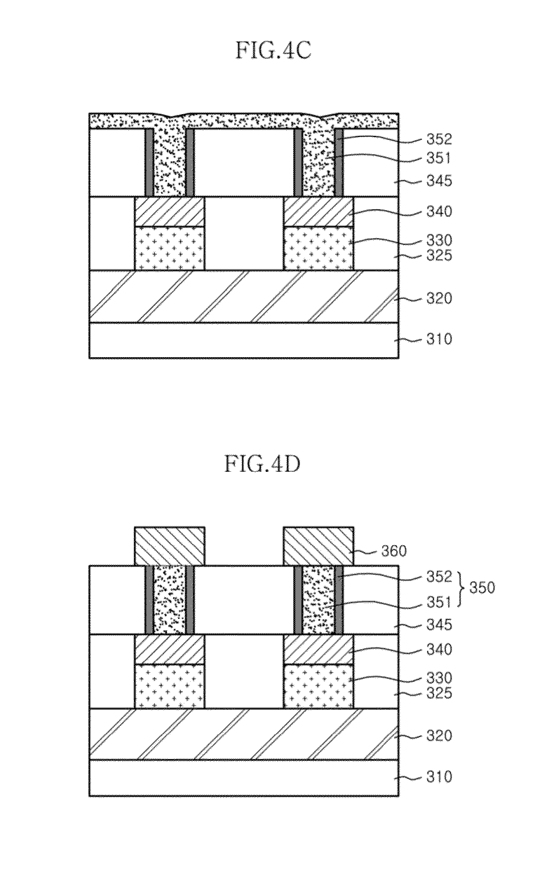

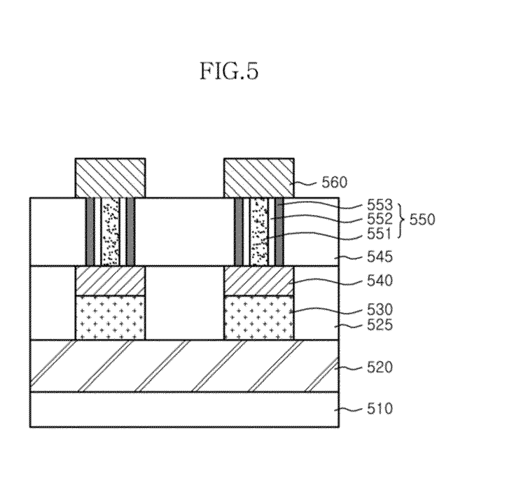

FIGS. 4A to 4D are cross-sectional views sequentially illustrating a method of manufacturing the resistive memory apparatus shown in FIG. 3.

As illustrated in FIG. 4A, a method of manufacturing the resistive memory apparatus may include forming a word line region 320. When a semiconductor substrate 310 is provided, the word line region 320 may be formed by implanting N type impurities into an upper portion of the provided semiconductor substrate 310 or forming a metal material on the semiconductor substrate 310. A first interlayer insulating layer 325 including a hole is formed on the word line region 320. A switching device 330 is formed in the hole, and a first electrode 340 formed of a metal material is formed on the switching device 330 in the hole. Next, a second interlayer insulating layer 345 is deposited, and a hole H is formed in the second interlayer insulating layer 345 through a process such as a photolithographic process to expose an upper surface of the first electrode 340.

As illustrated in FIG. 4B, a second resistance-variable material 352 is deposited on an upper surface of the second interlayer insulating layer 345 and a sidewall and a bottom of the hole pattern. The second resistance-variable material 352 may be deposited using an atomic layer deposition (ALD) method or a chemical vapor deposition (CVD) method. The second resistance-variable material 352 may include a material in which three elements are combined, such as GeSbTe, GaSeTe, or InSbTe as described above.

As illustrated in FIG. 4C, a portion of the second resistance-variable material 352 formed on the bottom of the hole H and the upper surface of the second interlayer insulating layer 345 is removed, for example, through an anisotropic etching process, and a first resistance-variable material 351 is formed to be buried in the hole H. The first resistance-variable material 351 may be formed in an amorphous state having very low surface roughness to prevent a void from being occurred in the hole. The first resistance-variable material 351 may include a material in which two elements are combined, such as SbSe, SbTe, GaSb, InSb, InSe, or GeTe as described above.

As illustrated in FIG. 4D, the first resistance-variable material 351 is planarized, for example, using a chemical mechanical polishing (CMP) method, to form a separated data storage unit 350. Next, a second electrode 360 is formed on the data storage unit 350. Although not shown, a bit line region may be formed on the second electrode 360.

FIG. 5 is a cross-sectional view illustrating a resistive memory apparatus according to another embodiment of the present invention.

Referring to FIG. 5, the resistive memory apparatus may include a word line region 520 serving as a word line and formed on a semiconductor substrate 510, a switching device 530 formed on the word line region 520, a first electrode (or a bottom electrode) 540 formed on the switching device 530, a data storage unit 550 formed on the first electrode 540, and a second electrode (or a top electrode) 560 formed on the data storage unit 550. The reference numerals 525 and 545 denote a first interlayer insulating layer and a second interlayer insulating layer.

The data storage unit 550 may be formed so that a width of the data storage unit 550 is smaller than an upper width of the first electrode 540. Therefore, a contact area of the first electrode 540 and the data storage unit 550 is reduced. This is because the contact area of the first electrode 540 and the data storage unit 550 is improved and a reset current of the resistive memory apparatus 100 is reduced.

The data storage unit 550 may include a first resistance-variable material 551 and a second resistance-variable material 553 having different thicknesses from each other and alternatively formed, and an insulating material 552 formed between the first resistance-variable material 551 and the second resistance-variable material 553 to insulate the first resistance-variable material 551 from the second resistance-variable material 553. The insulating material 552 may include a nitride material (e.g., a silicon nitride) or an oxide material (e.g., a silicon oxide). At this time, the first resistance-variable material 551, the insulating material 552, and the second resistance-variable material 553 are formed to be in contact with the first electrode 540 and extend upward from an upper surface of the first electrode 540.

That is, the first resistance-variable material 551 and the second resistance-variable material 553 are connected in parallel between the first electrode 540 and the second electrode 560. Further, the first resistance-variable material 551, the insulating material 552, and the second resistance-variable material 553 may be alternatively disposed two times or more in a lateral direction. That is, the data storage unit 550 may further include a third resistance-variable material surrounding a sidewall of the first resistance-variable material 551, another insulating material surrounding a sidewall of the third resistance-variable material, and the fourth resistance-variable is material surrounding a sidewall of another insulating material. Here, the third resistance-variable material may include the same material as the second resistance-variable material 553, the fourth resistance-variable material may include the same material as the first resistance-variable material 551, and the insulating materials may include the same material.

In the data storage unit 550, a resistance-variable material for the first resistance-variable material 551 is different from a resistance-variable material for the second resistance-variable material 553. As described above, the first resistance-variable material 551 may include a material in which two elements are combined, such as SbSe, SbTe, GaSb, InSb, InSe, or GeTe, and the second resistance-variable material 553 may include a material in which three elements are combined, such as GeSbTe, GaSeTe, or InSbTe. Thus, a SET resistance is changed depending on composition of the resistance-variable material. As described above in the embodiment, when composition ratios or kinds of the resistance-variable materials are changed, the resistances are changed depending on the composition ratios or kinds to support a multi-level cell.

The switching device 530 may be configured of any one among a PN diode, a Schottky diode, and a MOS transistor. When, the switching device 530 is configured of a diode, the memory cell may further include an ohmic contact layer that may improve adhesion between the diode and the first electrode 540 formed of a metal material.

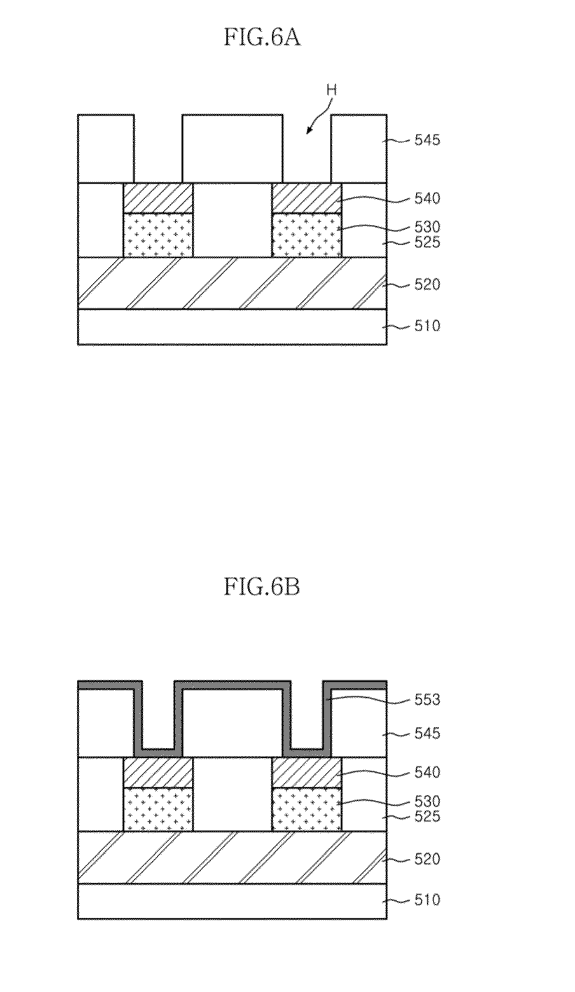

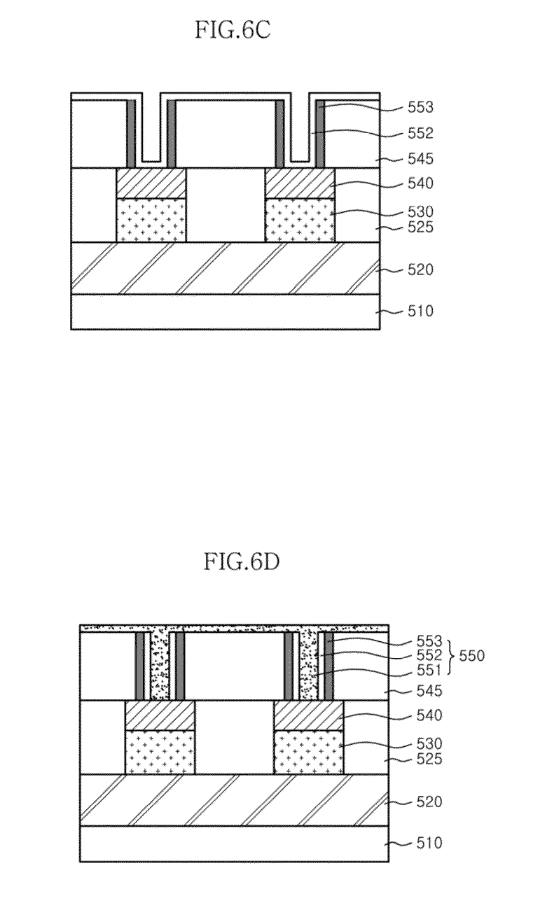

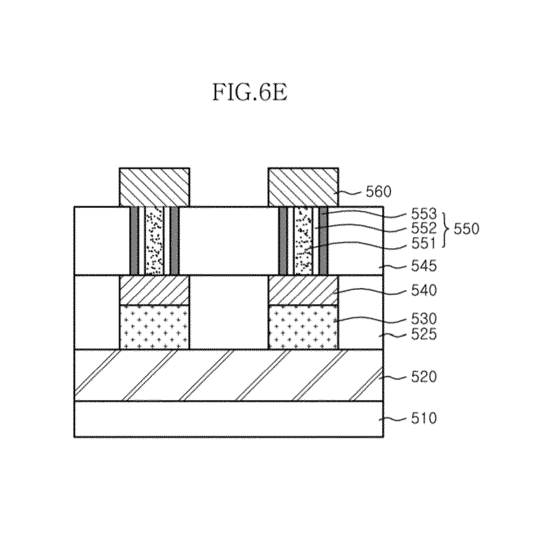

FIGS. 6A to 6D are cross-sectional views sequentially Illustrating a method of manufacturing the resistive memory apparatus shown in FIG. 5.

As illustrated in FIG. 6A, a method of manufacturing the resistive memory apparatus may include forming a word line region 520. When a semiconductor substrate 510 is provided, the word line region 520 may be formed by implanting N type impurities into an upper portion of the provided semiconductor substrate 510 or forming a metal material on the semiconductor substrate 510. A first interlayer Insulating layer 525 including a hole is formed on the word line region 520. A switching device 530 is formed in the hole, and a first electrode 540 formed of a metal material is formed on the switching device 530 in the hole. Next, a second interlayer insulating layer 545 is deposited, and a hole H is formed in the second interlayer insulating layer 545 through a process such as a photolithographic process to expose an upper surface of the first electrode 540.

As illustrated in FIG. 6B, a second resistance-variable material 553 is deposited on an upper surface of the second interlayer insulating layer 545 and a sidewall and a bottom of the hole pattern. The second resistance-variable material 553 may be deposited using an atomic layer deposition (ALD) method or a chemical vapor deposition (CVD) method. The second resistance-variable material 352 may include a material in which three elements are combined, such as GeSbTe, GaSeTe, or InSbTe as described above. As illustrated in FIG. 6C, a portion of the second resistance-variable material 553 formed on the bottom of the hole H and the upper surface of the second interlayer insulating layer 545 is removed. An insulating material 552 is deposited on the upper surface of the second interlayer insulating layer 545 and the sidewall and the bottom of the hole pattern in which the second resistance-variable material 553 is formed. The insulating material 552 may include a nitride material (e.g., a silicon nitride) or an oxide material (e.g., a silicon oxide).

As illustrated in FIG. 6D, a portion of the insulating material 552 formed on the bottom of the hole H and the upper surface of the second interlayer insulating layer 545 is removed. A first resistance-variable material 551 is formed to be buried in the hole H. The first resistance-variable material 551 may be formed in an amorphous state having very low surface roughness to prevent a void from being occurred in the hole H. The first resistance-variable material 551 may include a material in which two elements are combined, such as SbSe, SbTe, GaSb, InSb, InSe, or GeTe as described above.

As illustrated in FIG. 6E, the first resistance-variable material 551 is planarized, for example, using a chemical mechanical polishing (CMP) method, to form a data storage unit 550. Next, a second electrode 560 is formed on the data storage unit 550. Although not shown, a bit line region may be formed on the second electrode 560.

The resistive memory apparatuses according to the embodiments of the present invention may alternately form the first resistance-variable material 351 or 551 and the second resistance-variable material 352 or 553 having different resistances from each other or may form the first resistance-variable material 351 or 551 and the second resistance-variable material 352 or 553 having different thicknesses from each other to support a multi-level cell.

The above embodiment of the present invention is illustrative and not limitative. Various alternatives and equivalents are possible. The invention is not limited by the embodiment described herein. Nor is the invention limited to any specific type of semiconductor device. Other additions, subtractions, or modifications are obvious in view of the present disclosure and are intended to fall within the scope of the appended claims.

What is claimed is:

1. A resistive memory apparatus comprising:
a first electrode formed on a semiconductor substrate;
an insulating layer formed on the first electrode and including a hole exposing an upper surface of the first electrode;
a data storage unit in which a first resistance-variable material and a second resistance-variable material having different resistances from each other are alternately formed at least once in the hole; and
a second electrode formed on the data storage unit.

2. The resistive memory apparatus of claim 1, wherein the first resistance-variable material of the data storage unit has a different width from the second resistance-variable material of the data storage unit.

3. The resistive memory apparatus of claim 2, wherein the first resistance-variable material and the second resistance-variable material are formed to be in contact with the first electrode and to extend upward from an upper surface of the first electrode.

4. The resistive memory apparatus of claim 3, wherein the second resistance-variable material includes any one among GeSbTe, GaSeTe, and InSbTe.

5. The resistive memory apparatus of claim 3, wherein the first resistance-variable material includes any one among SbSe, SbTe, GaSb, InSb, InSe, and GeTe.

6. The resistive memory apparatus of claim 1, wherein a width of the hole formed in the insulating layer is smaller than that of the upper surface of the first electrode.

7. The resistive memory apparatus of claim 2, wherein the data storage unit further includes an insulating material formed between the first resistance-variable material and the second resistance-variable material.

8. A resistive memory apparatus, comprising:
a first electrode formed on a semiconductor substrate;
an insulating layer formed on the first electrode and including a hole exposing an upper surface of the first electrode;
a data storage unit formed in the hole and including at least two resistance-variable materials having different composition ratios from each other and formed to extend upward from the upper surface of the first electrode; and
a second electrode formed on the data storage unit.

9. The resistive memory apparatus of claim 8, wherein the at least two resistance-variable materials of the data storage unit have different widths from each other.

10. The resistive memory apparatus of claim 9, wherein a second resistance-variable material of the at least two resistance-variable materials includes any one among GeSbTe, GaSeTe, and InSbTe.

11. The resistive memory apparatus of claim 9, wherein a first resistance-variable material of the at least two resistance-variable materials includes any one among SbSe, SbTe, GaSb, InSb, InSe, and GeTe.

12. The resistive memory apparatus of claim 8, wherein a width of the hole formed in the insulating layer is smaller than that of the upper surface of the first electrode.

13. The resistive memory apparatus of claim 9, wherein the data storage unit further includes an insulating material formed between the first resistance-variable material and the second resistance-variable material.

14. A resistive memory apparatus, comprising:
a first electrode formed on a semiconductor substrate;
an interlayer insulating layer formed on the first electrode and including a hole exposing an upper surface of the first electrode;
a first data storage unit formed at a sidewall of the hole;
a second data storage unit formed to be buried in the hole;
an insulating layer formed between the first data storage unit and the second data storage unit; and
a second electrode formed on the first data storage unit, the insulating layer, and the second data storage unit.

15. The resistive memory apparatus of claim 14, wherein the second data storage unit includes any one among GeSbTe, GaSeTe, and InSbTe.

16. The resistive memory apparatus of claim 14, the first data storage unit includes any one among SbSe, SbTe, GaSb, InSb, InSe, and GeTe.

17. The resistive memory apparatus of claim 14, further comprising an insulating material formed between the first data storage unit and the second data storage unit to insulate the first data storage unit from the second data storage unit.

18. The resistive memory apparatus of claim 14, wherein a width of the hole formed in the insulating layer is smaller than that of the upper surface of the first electrode.

19. A resistive memory apparatus, comprising:
a memory cell array including memory cells, each memory cell including two or more resistance-variable materials for implementation of a multi-level cell having different resistances from each other and alternately formed; and
a control circuit suitable for controlling two-bit data or more among data input from the outside to be stored in a unit memory cell.

20. The resistive memory apparatus of claim 19, wherein the memory cell includes:
a data storage unit including a first resistance-variable material formed by combining three elements and a second resistance-variable material formed by combining two elements;
a switching device connected in series to the data storage unit; and
an electrode suitable for electrically connecting the data storage unit and the switching device.

21. The resistive memory apparatus of claim 20, wherein the data storage unit is formed so that the first resistance-variable material has a different width from the second resistance-variable material.

22. The resistive memory apparatus of claim 21, wherein the data storage unit is formed so that the first resistance-variable material and the second resistance-variable material are in contact with an upper surface of the electrode and extends upward from the upper surface of the electrode.

23. The resistive memory apparatus of claim 22, wherein the second resistance-variable material includes any one among GeSbTe, GaSeTe, and InSbTe.

24. The resistive memory apparatus of claim 22, wherein the first resistance-variable material includes any one among SbSe, SbTe, GaSb, InSb, InSe, and GeTe.

25. The resistive memory apparatus of claim 22, further comprising an insulating material formed between the first resistance-variable material and the second resistance-variable material.

26. A method of manufacturing a resistive memory apparatus, the method comprising:
forming a first electrode on a semiconductor substrate;
forming an insulating layer on the semiconductor substrate;
forming a hole exposing an upper surface of the first electrode by etching the insulating layer;
forming a data storage unit, including a first resistance-variable material and a second resistance-variable material having different resistances from each other, in the hole; and
forming a second electrode on the data storage unit.

27. The method of claim 26, wherein the first resistance-variable material and the second resistance-variable material are connected in parallel between the first electrode and the second electrode.

28. The method of claim 26, wherein the data storage unit further includes an insulating material, which is interposed between the first resistance-variable material and the second resistance-variable material.

29. The method of claim 27, wherein the first resistance-variable material and the second resistance-variable material are alternatively disposed two times or more in a lateral direction.

30. The method of claim 28, wherein the first resistance-variable material, the insulating material, and the second resistance-variable material are alternatively disposed two times or more in a lateral direction.

31. The method of claim 26, wherein a width of the hole is smaller than that of the upper surface of the first electrode.

32. The method of claim 26, wherein the forming of the data storage unit includes:
forming the first resistance-variable material on an upper surface of the insulating layer and a sidewall and a bottom of the hole;
removing a portion of the first resistance-variable material on the bottom of the hole and the upper surface of the insulating layer;
forming the second resistance-variable material to be buried in the hole; and
removing a portion of the second resistance-variable material formed on the upper surface of the insulating layer by performing a planarization process.

33. The method of claim 32, wherein
a thickness of the second resistance-variable material is different from that of the first resistance-variable material.

34. The method of claim 26, wherein the second resistance-variable material includes any one among GeSbTe, GaSeTe, and InSbTe.

35. The method of claim 34, wherein the first resistance-variable material includes any one among SbSe, SbTe, GaSb, InSb, InSe, and GeTe.

36. The method of claim 28, wherein the forming of the data storage unit includes:
forming the first resistance-variable material on an upper surface of the insulating layer and a sidewall and a bottom of the hole;
removing a portion of the first resistance-variable material on the bottom of the hole and the upper surface of the insulating layer;
forming the insulating material on the upper surface of the insulating layer and on the sidewall and the bottom of the hole in which the first resistance-variable material is formed;
removing a portion of the insulating material formed on the bottom of the hole and the upper surface of the insulating material;
forming a second resistance-variable material to be buried in the hole; and
removing a portion of the second resistance-variable material formed on the upper surface of the insulating layer by performing a planarization process.

37. A resistive memory apparatus, comprising:
a switching device coupled to a word line;
a first electrode coupled to the switching device;
a second electrode coupled to a bit line; and
a data storage unit including a first resistance-variable material and a second resistance-variable material having different resistances from each other,
wherein the first resistance-variable material and the second resistance-variable material are connected in parallel between the first electrode and the second electrode.

38. The resistive memory apparatus of claim 37, wherein the first resistance-variable material surrounds a sidewall of the second resistance-variable material.

39. The resistive memory apparatus of claim 37, wherein the data storage unit further includes a first insulating material, which is interposed between the first resistance-variable material and the second resistance-variable material.

40. The resistive memory apparatus of claim 37, wherein the data storage unit further includes a third resistance-variable material surrounding a sidewall of the first resistance-variable material and the fourth resistance-variable material surrounding a sidewall of the third resistance-variable material,
wherein the third resistance-variable material includes the same material as the second resistance-variable material, and
wherein the fourth resistance-variable material includes the same material as the first resistance-variable material.

41. The resistive memory apparatus of claim 39, wherein the data storage unit further includes a third resistance-variable material surrounding a sidewall of the first resistance-variable material, the second insulating material surrounding a sidewall of the third resistance-variable material, and the fourth resistance-variable material surrounding a sidewall of the second insulating material,
wherein the third resistance-variable material includes the same material as the second resistance-variable material,
wherein the second insulating material includes the same material as the first insulating material, and
wherein the fourth resistance-variable material includes the same material as the first resistance-variable material.

42. The resistive memory apparatus of claim 38, wherein the second resistance-variable material includes any one among GeSbTe, GaSeTe, and InSbTe.

43. The resistive memory apparatus of claim 42, wherein the first resistance-variable material includes any one among SbSe, SbTe, GaSb, InSb, InSe, and GeTe.

44. The resistive memory apparatus of claim 39, wherein the first insulating material includes a silicon nitride or a silicon oxide.

45. The resistive memory apparatus of claim 43, wherein a thickness of the second resistance-variable material is different from that of the first resistance-variable material.
